(19) United States
(12) Patent Application Publication
(10) Pub. No.: US 2021/0055098 A1
(43) Pub. Date: Feb. 25, 2021

(54) Charged Particle Beam System and Overlay Shift Amount Measurement Method

(71) Applicant: Hitachi High-Tech Corporation, Tokyo (JP)

(72) Inventors: Takuma YAMAKI, Tokyo (JP); Takuma YAMAMOTO, Tokyo (JP); Yasunori GOTO, Tokyo (JP); Tomohiro TAMORI, Tokyo (JP); Kazunari ASAO, Tokyo (JP)

(21) Appl. No.: 16/887,885

(22) Filed: May 29, 2020

(30) Foreign Application Priority Data
Aug. 20, 2019 (JP) 2019-150662

(51) Int. Cl. G01B 15/00; G01N 23/2251; G01N 23/203

(52) U.S. Cl. CPC G01B 15/00; G01N 23/2251; G01N 23/203; G01N 2223/045; G01B 2210/56; G01N 2223/071; G01N 2223/401; G01N 2223/6116; G01N 2223/053

(57) ABSTRACT

Overlay shift amount measurement with high accuracy becomes possible. A charged particle beam system includes a computer system that measures an overlay shift amount between a first layer of a sample and a second layer lower than the first layer based on output of a detector. The computer system generates first images with respect to the first layer and second images with respect to the second layer based on the output of the detector, generates a first added image by adding the first images by a first added number of images, and generates a second added image by adding the second image by a second added number of images greater than the first added number of images. An overlay shift amount between the first layer and the second layer is measured based on the first added image and the second added image.

### TECHNICAL FIELD

The present invention relates to a charged particle beam system and an overlay shift amount measurement method.

### BACKGROUND ART

A semiconductor device is manufactured by performing a process of transferring a pattern formed on a photomask onto a semiconductor wafer using lithography processing and etching processing and repeating this process. During the process of manufacturing a semiconductor device, the quality of lithography and etching processing, generation of foreign matters, and the like greatly affect the yield of semiconductor devices to be manufactured. Therefore, it is important to detect the occurrence of an abnormality or a defect in the manufacturing process early or in advance in order to improve the yield of semiconductor devices.

Therefore, in the manufacturing process of a semiconductor device, a pattern formed on a semiconductor wafer is measured or inspected. Particularly, with the recent progress in miniaturization and three-dimensionalization of semiconductor devices, it has become increasingly important to accurately measure and control overlay shift amounts of patterns between different processes.

In devices in the related art, positions of patterns generated in each process are measured based on reflected light obtained by irradiating a semiconductor device with light to measure the overlay shift amounts of patterns among different processes. However, with the progress of miniaturization of patterns, it becomes difficult to obtain required detection accuracy using a method of detecting a shift amount with light. Therefore, there is a growing need to measure overlay shift amounts of the patterns using a scanning electron microscope with higher resolution than light.

For example, PTL 1 discloses a technique of detecting a secondary electron and a backscattered electron, and applying an optimal contrast correction to each of them, to measure an overlay shift amount between different layers (an upper layer and a lower layer) with high accuracy. However, as described in PTL 1, when the overlay shift amount between the upper layer pattern and the lower layer pattern is measured by the scanning electron microscope, a signal from the lower layer has more noise than a signal from the upper layer. Therefore, in the device of PTL 1, a plurality of acquired images are added to improve a signal-to-noise ratio (SN ratio), thereby realizing measurement with high accuracy on an overlay shift amount.

However, in this method, when a measurement target is irradiated with the charged particle beam plural times in order to add a plurality of images, a shape change may occurs in the upper layer, which is highly sensitive to the charged particle beam. As a result, there may be a problem that accurate information on the shape of the upper layer cannot be obtained. However, if the number of added images is reduced to avoid the problem, the S/N ratio of the image of the lower layer decreases, and accurate information on the lower layer cannot be obtained. As described above, in the above method, there is a problem that it is difficult to obtain high measurement accuracy for the overlay shift amount.

### CITATION LIST

### Patent Literature

PTL 1: WO-2014-181577

### SUMMARY OF INVENTION

### Technical Problem

An object of the present invention is to provide a charged particle beam system and an overlay shift amount measurement method that can measure an overlay shift amount with high accuracy.

### Solution to Problem

In order to achieve the above object, a charged particle beam system according to the present invention includes a charged particle beam irradiating unit that irradiates a sample with charged particle beams; a detector that detects a signal from the sample; and a computer system that measures an overlay shift amount between a first layer of the sample and a second layer lower than the first layer based on output of the detector. The computer system generates first images with respect to the first layer and second images with respect to the second layer based on the output of the detector, generates a first added image by adding the first images by a first added number of images, and generates a second added image by adding the second images by a second added number of images greater than the first added number of images. The overlay shift amount between the first layer and the second layer is measured based on the first added image and the second added image.

According to the present invention, an overlay shift amount measurement method of measuring an overlay shift amount between different layers of a sample based on a signal detected by a detector by irradiating the sample with charged particle beams includes a step of generating first images with respect to a first layer of the sample and second images with respect to a second layer lower than the first layer based on an output of the detector; a step of generating a first added image by adding the first images by a first added number of images and generating a second added image by adding the second images by a second added number of images greater than the first added number of images; and a step of measuring an overlay shift amount between the first layer and the second layer based on the first added image and the second added image.

### Advantageous Effects of Invention

According to the present invention, it is possible to provide a charged particle beam system and an overlay shift amount measurement method that can measure an overlay shift amount with high accuracy.

### BRIEF DESCRIPTION OF DRAWINGS

FIG. 1 is a schematic diagram illustrating a schematic configuration of a scanning electron microscope (SEM) of a first embodiment.

FIG. 2 is a schematic diagram illustrating operations of units of the scanning electron microscope (SEM) of the first embodiment.

FIG. 3A and FIGS. 3B to 3D are a perspective view and cross-sectional views for describing an example of a structure of a sample to be a target of an overlay shift amount measurement in a charged particle beam system of the first embodiment.

FIG. 4 is a flowchart for describing an example of a procedure (recipe setting flow) of the overlay shift amount measurement according to the first embodiment.

FIG. 5 is a flowchart for describing an example of a procedure (measurement performing flow) of the overlay shift amount measurement according to the first embodiment.

FIG. 6 is a flowchart for describing an example of a procedure (recipe setting (template registration) flow) of the overlay shift amount measurement according to the first embodiment.

FIG. 7 is a flowchart for describing an example of a procedure (measurement performing flow) of the overlay shift amount measurement according to the first embodiment.

FIG. 8 describes an example of a GUI screen for performing template registration (Step S303) and measurement point registration (Step S304) of FIG. 4.

FIG. 9 is an example of an acquisition condition setting screen.

FIGS. 10A and 10B are schematic diagrams for describing details of position shift amount calculation (Step S404) in the measurement performing flow (FIG. 5).

FIG. 11 is an example of an acquisition condition setting screen according to a second embodiment.

FIG. 12 is an example of an acquisition condition setting screen according to a third embodiment.

FIG. 13 is an example of adrift correction condition setting screen according to the third embodiment.

FIG. 14 is a schematic diagram for describing a method of detecting a drift shift amount according to the third embodiment.

### DESCRIPTION OF EMBODIMENTS

Hereinafter, the present embodiment is described with reference to the accompanying drawings. In the accompanying drawings, functionally the same elements may be represented by the same reference numbers. The accompanying drawings illustrate embodiments and implementation examples in accordance with the principle of the present disclosure, but the drawings are provided for understanding of the present disclosure, and are not used for construing the present disclosure in a limited way. The description in the present specification is provided as typical examples and is not intended to limit the scope of the claims or the application of the disclosure in any way.

In the present embodiment, description has been made in sufficient detail for those skilled in the art to implement the present disclosure. However, other implementations and forms are also possible, and it is necessary to understand that the configuration or structure can be changed and various elements can be replaced without departing from the scope and spirit of the technical idea of the present disclosure. Therefore, the following description should not be construed as being limited thereto.

In the embodiments described below, a scanning electron microscope is mainly described as an example of a charged particle beam system. However, a scanning electron microscope is merely an example of a charged particle beam system, and the present invention is not limited to the embodiments described below. The charged particle beam system according to the present invention broadly includes a device that acquires information of a target using charged particle beams. Examples of the charged particle beam system include an inspection device including a scanning electron microscope, a shape measurement device, and a defect detection device. Of course, the system can also be applied to a general-purpose electron microscope and a processing apparatus including an electron microscope.

A system in which the above charged particle beam system is connected by a signal line and a multifunction device including a charged particle beam system are also included. In the following embodiments, a method of measuring an overlay shift amount between two layers in a semiconductor wafer is described with the semiconductor wafer as a measurement target. However, this method is also an example for the description, and the present invention is not limited to the specifically described example. For example, the term of “overlay shift amount measurement” includes not only a case of two layers but also a case of three or more layers, and may include not only a position shift of patterns among respective layers but also a position shift of patterns in the same layer.

### First Embodiment

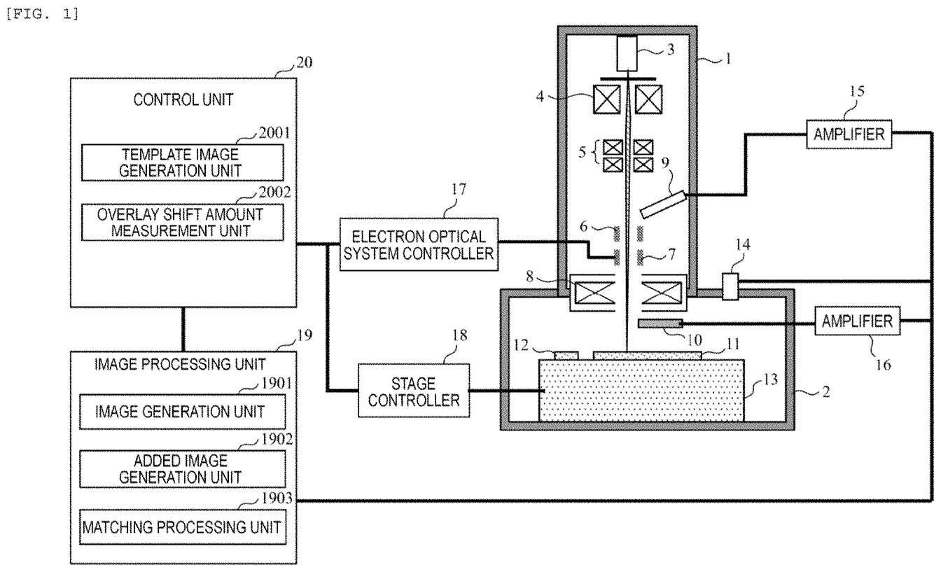

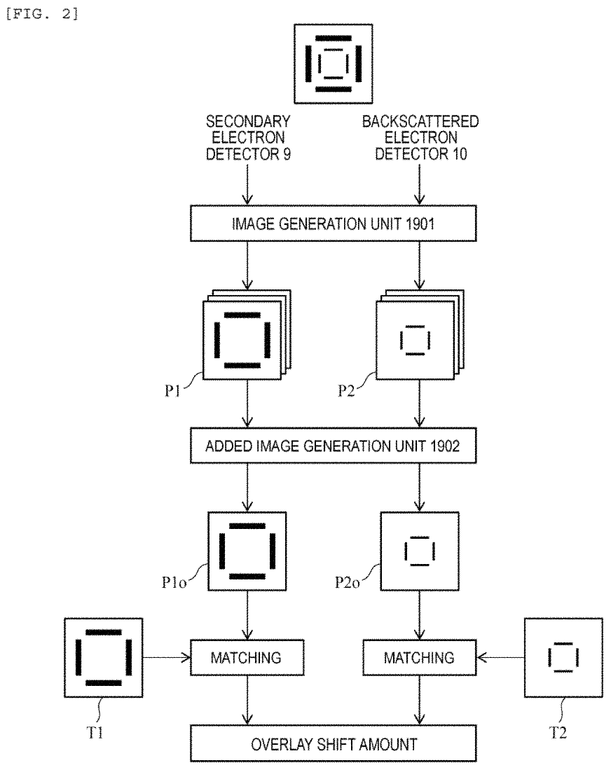

Referring to FIGS. 1 and 2, according to the first embodiment, a charged particle beam system including an overlay shift amount measuring function is described. This charged particle beam system is, for example, a scanning electron microscope (SEM) and is configured to be able to perform a method of measuring an overlay shift amount in which an overlay shift amount between an upper layer pattern and a lower layer pattern is measured by using an image acquired by the irradiation of electron beams which are charged particle beams. FIG. 1 is a schematic diagram illustrating a schematic configuration of a scanning electron microscope (SEM) of the first embodiment, and FIG. 2 is a schematic diagram illustrating operations of units.

The SEM includes a column 1 and a sample chamber 2 which are an electron optical system. The column 1 includes an electron gun 3 that generates electron beams (charged particle beams) for irradiation, a condenser lens 4, an aligner 5, an ExB filter 6, a deflector 7, and an objective lens 8, and functions as a charged particle beam irradiating unit. The condenser lens 4 and the objective lens 8 focus electron beams generated by the electron gun 3 and to be irradiated on a wafer 11 as a sample. The deflector 7 deflects electron beams according to an applied voltage in order to scan the wafer 11 with the electron beams. The aligner 5 is configured to generate an electric field for aligning electron beams with respect to the objective lens 8. The ExB filter 6 is a filter for introducing secondary electrons emitted from the wafer 11 to a secondary electron detector 9.

The column 1 and the sample chamber 2 are provided with the secondary electron detector 9 (first detector) for detecting secondary electrons from the wafer 11 (sample) and a backscattered electron detector 10 (second detector) for detecting backscattered electrons from the wafer 11. The wafer 11 is mounted on an XY stage 13 installed in the sample chamber 2. In addition to the wafer 11, a standard sample 12 for beam calibration can be mounted on the XY stage 13. The standard sample 12 is fixed to the XY stage 13, the XY stage 13 is moved according to a signal from a stage controller 18, and the position of the standard sample 12 with respect to the column 1 is determined. In order to align the wafer 11, an optical microscope 14 for optically observing the wafer 11 is provided above the XY stage 13.

The SEM further includes amplifiers 15 and 16, an electron optical system controller 17, the stage controller 18, an image processing unit 19, and a control unit 20. The image processing unit 19 and the control unit 20 integrally form a computer system. The amplifiers 15 and 16 amplify detection signals from the secondary electron detector 9 and the backscattered electron detector 10 and output the amplified detection signals to the image processing unit 19. The electron optical system controller 17 controls the aligner 5, the ExB filter 6, the deflector 7, and the like in the column 1 according to the control signals from the control unit 20.

The stage controller 18 outputs a drive signal for driving the XY stage 13 according to the control signal from the control unit 20. The control unit 20 can be configured, for example, with a general-purpose computer.

The image processing unit 19, for example, includes an image generation unit 1901, an added image generation unit 1902, and a matching processing unit 1903. The image processing unit 19 can be configured with a general-purpose computer, and the image generation unit 1901, the added image generation unit 1902, and the matching processing unit 1903 can be realized in the image processing unit 19 by a processor, a memory, and a built-in computer program included in the image processing unit 19 (not illustrated).

The image generation unit 1901 generates images P1 (first images P1) of a surface (first layer) of the wafer 11 obtained based on the secondary electrons and images P2 (second images P2) of a layer (second layer) lower than the surface obtained based on the backscattered electrons according to the amplified detection signals received from the amplifiers 15 and 16. The image generation unit 1901 may include a function of performing edge extraction processing, smoothing processing, and other image processing on the obtained image.

As illustrated in FIG. 2, the added image generation unit 1902 adds the plurality of first images P1 or the plurality of second images P2 obtained by a plurality of times of irradiation with charged particle beams by a designated added number of images to generate a first added images P1o and a second added images P2o, respectively. As described below, the added number of images for generating the second added images P2o is set to a number greater than the added number of images for generating the first added images P1o. This is because the first images P1 are images on the surface with higher electron beam sensitivity while the second images P2 are images on the lower layer with lower electron beam sensitivity.

As illustrated in FIG. 2, the matching processing unit 1903 matches the first added images P1o with a template image T1 for the first added images P1o and extracts an image that matches the template image T1 from the first added image P1o. The matching processing unit 1903 matches the second added images P2o with a template image T2 for the second added images P2o and extracts an image that matches the template image T2 from the first added image P2o.

According to the matching results, in the control unit 20, an overlay shift amount between the wafer surface and the lower layer is measured. Here, the presence or absence and the strength of the smoothing processing and the presence or absence of the edge extraction processing can be made selectable for each image.

The control unit 20 controls the entire scanning electron microscope (SEM) via the electron optical system controller 17 and the stage controller 18. Although not illustrated, the control unit 20 can include an input unit such as a mouse or a keyboard for enabling a user to input instructions, a display unit for displaying a captured image or the like, and a storage unit such as a hard disk or a memory.

For example, the control unit 20 can include a template image generation unit 2001 that generates the template image and an overlay shift amount measurement unit 2002 that measures an overlay shift amount. The control unit 20 can be configured with a general-purpose computer, and the template image generation unit 2001 and the overlay shift amount measurement unit 2002 are realized in the control unit 20 by a processor, a memory, and a built-in computer program included in the control unit 20 (not illustrated). In addition to the above, the charged particle beam system can include a control unit of each component and an information line between components (not illustrated).

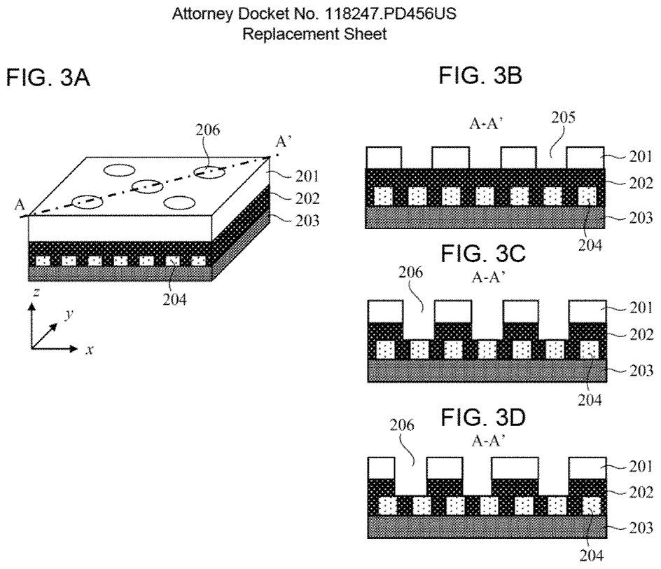

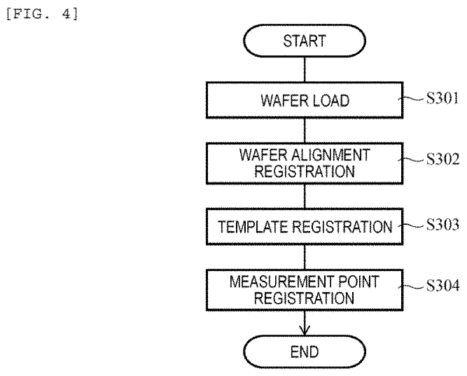

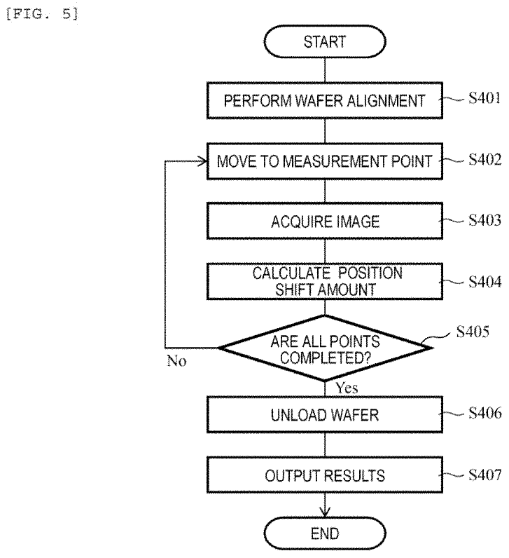

With reference to FIGS. 3(a) to 3(d), an example of the structure of a sample to be a target of overlay shift amount measurement in the charged particle beam system of the first embodiment is described. FIG. 3(a) is an example of a schematic diagram (perspective diagram) represented by a laminate structure of the sample. In the sample, a silicon oxide 203 which is a wafer material is positioned on the lowermost layer, and lower layers 204 made of a metal material such as aluminum are formed on the silicon oxide 203. An intermediate layer 202 made of an insulating material is deposited on the silicon oxide 203 and the lower layers 204, and also an upper layer 201 is positioned on the surface (uppermost layer) of the intermediate layer 202. Columnar contact holes 206 reaching the lower layer 204 are formed in the upper layer 201 and the intermediate layer 202. Lower ends of the contact holes 206 reach the surface of the lower layer 204. The upper layer 201 is a protective layer that protects the intermediate layer 202.

FIGS. 3(b) to 3(d) are cross-sectional views taken along line A-A′ in FIG. 3(a) for describing a process of forming the contact holes 206. FIG. 3(b) is a cross-sectional view for describing a stage where holes 205 are formed by etching to reach the surface of the intermediate layer 202. In addition to the stage of FIG. 3 (b), etching processing is performed with the upper layer 201 as a protective layer, and as illustrated in FIG. 3 (c), the contact holes 206 reaching the surface of the lower layer 204 from the surface of the upper layer 201 are formed.

The contact holes 206 are filled with a conductive material by a process (for example, a CVD process) after the etching processing. Thereby, a part of the lower layer 204 is electrically connected to upper layer wiring (not illustrated) via the embedded conductive material (contact).

FIGS. 3 (b) and 3 (c) illustrate an example in which the holes 205 (the contact holes 206) are appropriately formed to be smaller than the predetermined overlay shift amount. In this manner, when the overlay shift amount is less than the predetermined value, the lower layer 204 and the upper layer wiring can be normally connected by the contact.

However, as illustrated in FIG. 3 (d), the overlay shift amount with respect to the lower layer 204 of the contact hole 206 is greater than an allowed value, the conductive material that fills the contact holes 206 may be in contact with a plurality of members positioned in the lower layer 204. In this case, compared with a case where the overlay shift does not occur, the performance of the circuit changes, the semiconductor device finally manufactured may not normally operate. Therefore, it is important to measure the overlay shift amount with high accuracy.

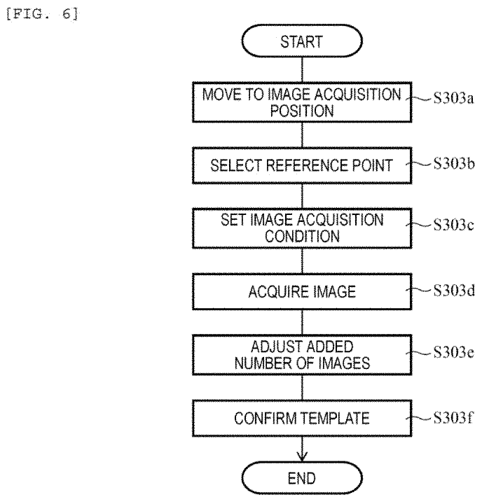

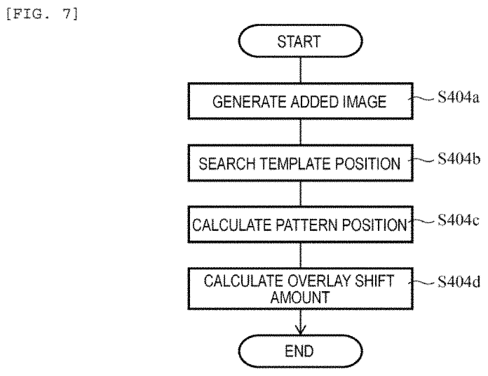

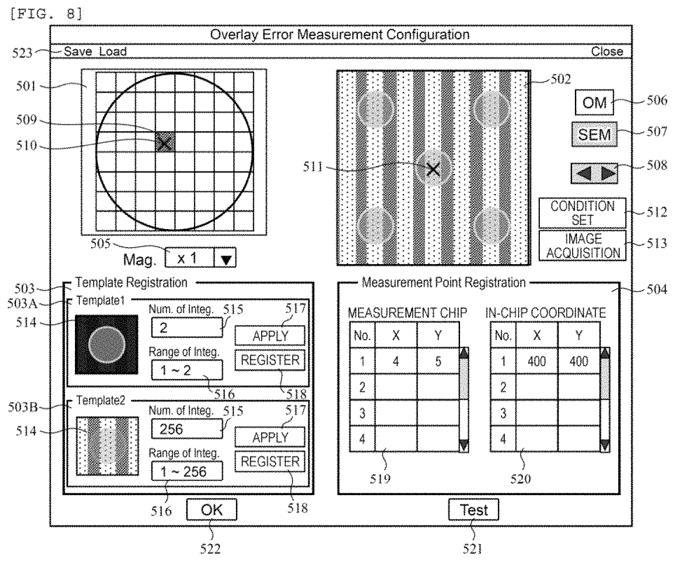

Hereinafter, with reference to flowcharts of FIGS. 4 to 7, an example of a procedure of the overlay shift amount measurement according to the present embodiment is described. The overlay shift amount measurement is realized by performing a recipe setting flow for the overlay shift amount measurement illustrated in FIG. 4 and a measurement performing flow illustrated in FIG. 5. FIG. 6 is a flowchart for describing details of the procedure of the template registration (Step S303) in the recipe setting flow of FIG. 4. FIG. 7 is a flowchart for describing details of the procedure of the overlay shift amount calculation (Step S404) in the measurement performing flow of FIG. 5. The recipe is a collection of settings for automatically and semi-automatically executing a series of measurement sequences. The template is a collection of information of a template image, an image acquisition condition, an added number of images, and the like and a collection of data for performing the overlay shift amount measurement.

With reference to FIG. 4, the recipe setting flow is described. The wafer 11 which is an object of the overlay shift amount measurement is loaded in the sample chamber 2 (Step S301). Subsequently, a wafer alignment for matching a coordinate system of the wafer 11 and a coordinate system of a device is performed, and the wafer alignment information as the result thereof is registered (Step S302).

Thereafter, with respect to the acquired images, the template is registered (Step S303), and a measurement point which is a measurement target on the wafer 11 for measuring the overlay shift amount is registered (Step S304). The details of the registration of the template are described below. By the above procedures, the recipe for the overlay shift amount measurement is created, and in the subsequent measurement performing flow, the overlay shift amount is measured based on the created recipe.

Subsequently, with reference to FIG. 5, the measurement performing flow is described. First, according to the wafer alignment information registered in the wafer alignment registration (Step S302), the wafer is aligned (Step S401). Subsequently, the wafer is moved to the measurement point registered in the measurement point registration (Step S304) (Step S402), and images are acquired in the image acquisition condition determined by the registered template in the template registration (Step S303) (Step S403).

When the images (the added images P1o) on the surface (upper layer) of the wafer 11 and the images (the added images P2o) on the lower layer are acquired, a process of matching the acquired added images P1o and P2o with the template images T1 and T2 is performed, and according to the result thereof, the overlay shift amount of the upper layer and the lower layer is calculated (Step S404). The calculation of the overlay shift amount is described below.

The operations of Steps S402 to S404 are continued until the measurement at all measurement points registered in the measurement point registration (Step S304) is completed. When a measurement point at which the measurement is not completed remains (No in Step S405), the wafer is moved to a next measurement point (Step S402), and when the measurement at all of the measurement points is completed, the wafer 11 is unloaded from the sample chamber 2 (Step S406). Thereafter, the measurement result is output, and the measurement performing flow ends (Step S407).

Subsequently, with reference to the flowchart of FIG. 6, the details of the template registration (Step S303) in the recipe setting flow is described.

First, in order to acquire the template image, the wafer 11 is moved to the designated image acquisition position (Step S303a). Subsequently, the reference point of the template image is selected (Step S303b), and then an acquisition condition of the image used as the template image is set (Step S303c). Also, around the selected reference point, under the set image acquisition condition, the first images P1 of the surface of the wafer 11 and the second images P2 of the lower layer are acquired (Step S303d). When the added number of images with respect to the first images P1 and the second images P2 are adjusted (Step S303e), the template is determined (Step S303f).

Subsequently, with reference to the flowchart of FIG. 7, the details of the position shift amount calculation (S404) in the measurement performing flow (FIG. 5) are described.

When the first images P1 and the second images P2 are acquired under the condition set in the recipe, the first images P1 and the second images P2 are added by using the number of added images and an added image range set in the recipe, and the first added images P1o and P2o are generated (Step S404a). Here, the expression “the number of added images” refers to data indicating how many images are added to generate the first added images P1o or the second added images P2o. The expression “added image range” refers to data relating to images from what number to what number are to be used among the plurality of captured images.

As described above, with respect to the number of added images, the added number of the second images P2 which are the images of the lower layer with lower electron beam sensitivity is set to be larger than the added number of the first images P1 which are the images of the surface with higher electron beam sensitivity. For example, the number of added images can be set by adding two first images P1 for the first added images P1o and adding 256 second images P2 for the second added images P2o.

With respect to the first added images P1o, among the 256 captured first images P1, the first and second images (two images in total) of the first images P1 from the first are added, whereby the added image range can be set as “1 to 2”. This is because, among the plurality of images, initially captured images cause less influence to a pattern formed by the irradiation with the electron beams. The input of the added image range can be omitted. In this case, with respect to the first added images P1o, among the plurality of captured images, initially captured images may be automatically selected by the control unit 20.

Meanwhile, with respect to the second added images P2o, all of the 256 captured second images P2 are targeted to be added, and the added image range can be set as “1 to 256”. Since the SN ratio of the image of the lower layer is likely to be lower than that of the upper layer, it is possible to acquire an image with a higher SN ratio by increasing the added number of images.

Subsequently, with respect to the generated first added images P1o and the generated second added images P2o, positions of the images matching with the template images T1 and T2 registered in the recipe are searched (Step S404b). The position of a pattern to be the overlay shift amount measurement target is calculated by searching the positions of the matching images (Step S404c). The position of the image matching with the template image can be searched by an algorithm such as a normalized correlation or a phase-only correlation.

When positions of patterns which are the overlay shift amount measurement targets for the first added images P1o and the second added images P2o are calculated, according to this calculation results, an overlay shift amount between the upper layer and the lower layer is calculated (Step S404d). The overlay shift amount may be any index indicating a position relationship between the patterns, may be calculated as a simple difference between coordinates, and may be calculated as a difference to which a preset offset amount or the like is added.

With reference to FIG. 8, an example of a GUI screen for performing the template registration (Step S303) and the measurement point registration (Step S304) is described. For example, this GUI screen includes a wafer map display area 501, an image display area 502, a template registration area 503, and a measurement point registration area 504.

The wafer map display area 501 is an area for displaying a shape of the wafer 11 on a map. The magnification for displaying the wafer map display area 501 can be changed by a wafer map magnification setting button 505.

The image display area 502 is an area where an optical microscope image obtained by capturing the wafer 11 with the optical microscope 14 or a SEM image can be selectively displayed. On the right side of the image display area 502, an OM button 506 and a SEM button 507 are displayed, the optical microscope image and the scanning electron microscope image can be selectively displayed on the image display area 502 by clicking these buttons. By operating a magnification change button 508, the magnification for displaying an image on the image display area 502 can be changed.

The template registration area 503 is an area for performing various kinds of input for registering the template images T1 and T2. The template registration area 503 includes a first screen (Template 1) 503A for registering the template image T1 for the first images P1 and a second screen (Template 2) 504B for registering the template image T2 for the second images P2.

The first screen 503A and the second screen 503B each include a template image display area 514, an added number adjustment area 515, an added image range adjustment area 516, an apply button 517, and the registration button 518.

The template image display area 514 is an area for displaying an image acquired as the template image T1 or T2. After performing the condition setting on the acquisition condition of an image to be used in the template image by clicking a condition setting button 512, an image acquisition button 513 is pressed so that an image to be a template image is displayed in the template image display area 514.

The added number adjustment area 515 is a display and input portion for displaying and adjusting the added number of images set with respect to the first images P1 or the second images P2. An added image range adjusting unit 516 is a display and input portion for displaying and adjusting an added image range set with respect to the first images P1 or the second images P2.

In the example of FIG. 8, as initial values, the number of added images and the added image range set in Step S303c are displayed. When an acquired image is not an image suitable for the measurement, the values of the added number adjustment area 515 and the added image range adjustment area 516 are changed by operating a mouse or a keyboard (not illustrated), and the apply button 517 is clicked, whereby the adjusted image is displayed in the template image display area 514. After the added number of images is adjusted, the template is determined by clicking the registration button 518.

The measurement point registration area 504 includes a measurement chip setting area 519 and an in-chip coordinate setting area 520. By inputting in-wafer coordinates of a chip and in-chip coordinates of the measurement points to be measured to each area, the measurement points for measuring the overlay shift amounts using the confirmed templates are registered. The screen of the example of FIG. 8 includes a recipe trial button 521 and a recipe confirmation button 522. The recipe trial button 521 is a button for instructing a trial for authenticating the recipe condition set as the recipe. The recipe confirmation button is a button to be pressed when the input recipe is confirmed after the trial directed by the recipe trial button 521. An overlay shift amount measurement setting screen operating area 523 is an area for saving and loading the recipe condition.

With reference to FIG. 8, the operation procedure when the template image is registered is described. First, by clicking an arbitrary position in the wafer map display area 501, the wafer 11 is moved to the clicked position (Step S303a of FIG. 4). In FIG. 8, a highlight display 509 in the wafer map display area 501 indicates the position of a currently displayed chip. Across mark 510 indicates a current position.

When the current position is displayed in the image display area 502, by an operation of a mouse or the like (not illustrated) by a user, the reference point of the template is selected in an arbitrary position in the image display area 502 (Step S303b of FIG. 4). A reference point cross mark 511 in the image display area 502 indicates the selected reference point.

After the reference point selection, when the condition setting button 512 is clicked, an acquisition condition setting screen described below is displayed. With this acquisition condition setting screen, the image acquisition condition is set (Step S303c of FIG. 4).

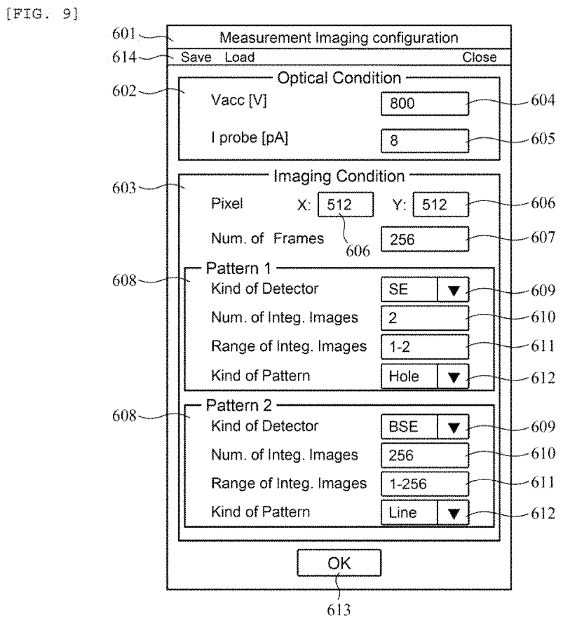

FIG. 9 is an example of the acquisition condition setting screen. An acquisition condition setting screen 601 exemplified in FIG. 9 includes an optical condition setting area 602 and an image generating condition setting area 603. In an acceleration voltage setting area 604 and a probe current setting area 605 of the optical condition setting area 602, an acceleration voltage of primary electrons and the probe current can be set, respectively.

For example, the image generating condition setting area 603 includes an acquired image pixel setting area 606, an acquired image frame number setting area 607, and a pattern condition setting area 608. By setting the acquired image pixel in the acquired image pixel setting area 606, the range for scanning electron beams around the reference point 511 can be determined. In the acquired image frame number setting area 607, the number of the acquired image frames, that is, the number of acquired images can be determined. In the present embodiment, since the overlay shift amount measurement with respect to each pattern of the upper layer and the lower layer is performed, two pattern condition setting areas 608 are arranged, but the present invention is not limited to the present form.

For example, the pattern condition setting area 608 includes a detector setting area 609, an added image number setting area 610, an added image range setting area 611, and a pattern type setting area 612. Conditions suitable for the measurement pattern are set for each area. For example, in the present embodiment, an image obtained by adding the first and second images (two images in total) detected with the secondary electron detector 9 by the electron beam irradiation to the hole pattern can be set as the template image T1 of the upper layer, and an image obtained by adding the first to 256-th images (256 images in total) detected with the backscattered electron detector 10 by the electron beam irradiation to the line pattern can be set as the template image T2 of the lower layer. After the acquisition condition confirmation of the image, by clicking a condition confirmation button 613, the acquisition condition is stored in the control unit 20. With a setting screen operation area 614, saving and loading of the set acquisition conditions become possible, the once set acquisition conditions of the image can be reused.

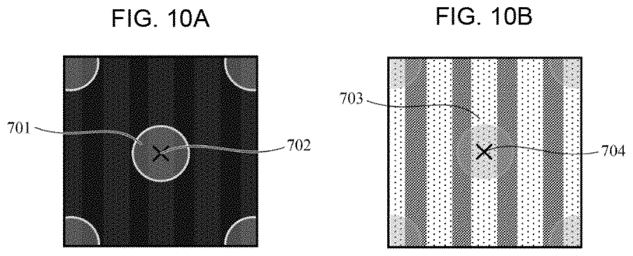

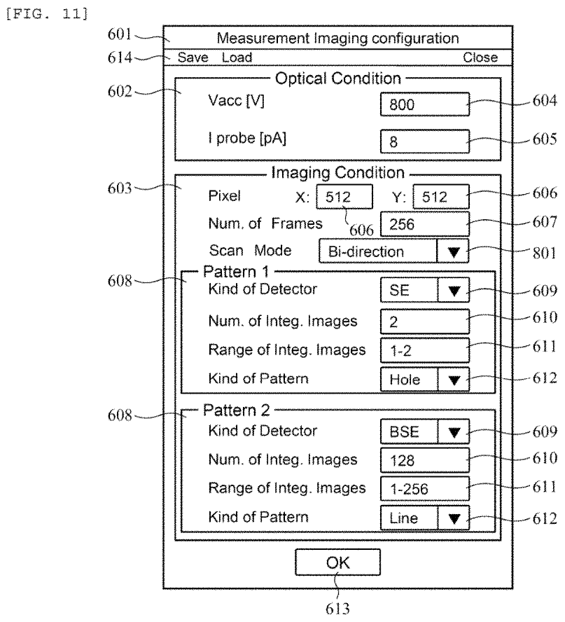

Subsequently, with reference to FIGS. 10(a) and 10(b), the details of the position shift amount calculation (Step S404) in the measurement performing flow (FIG. 5) are described. In the example of FIGS. 10(a) and 10(b), coordinates of a position 702 of the center of gravity of a hole pattern 701 of the upper layer are calculated (FIG. 10(a)), and coordinates of a position 704 of the center of gravity of a line pattern 703 of the lower layer are calculated. Positions of various patterns can be specified, for example, by a position of the center of gravity, but the position of the center of gravity is an example, and the present invention is not limited thereto. For example, the positions may be any position for characterizing relative and absolute coordinates of the patterns, and geometric center positions may be calculated.

As illustrated in FIGS. 10(a) and 10(b), after the positions of the upper layer and lower layer patterns are calculated, shift amounts of the positions of the upper layer and lower layer patterns are calculated, and these can be calculated as overlay shift amounts. The overlay shift amount may be any index indicating a position relationship of a pattern, and may be a simple difference of coordinates or a difference to which a preset offset amount and the like are added.

As described above, according to the first embodiment, when overlay shift amounts between a plurality of layers are measured, an added image is generated by setting the number of times of the addition of images in the image of the lower layer to be greater than that in the image of the upper layer, and the overlay shift amount is measured according to this added image. With respect to the upper layer, since only images that are less affected by the deformation of the pattern due to the charged particle beams are added, the shape of the pattern can be correctly captured, while with respect to the image of the lower layer with the lower SN ratio, the SN ratio can be increased by increasing the added number of images. Therefore, according to the first embodiment, it is possible to provide the charged particle beam system that can measure an overlay shift amount with high accuracy, and a method of measuring an overlay shift amount.

### Second Embodiment

Next, a scanning electron microscope (SEM) as a charged particle beam system according to a second embodiment is described with reference to FIG. 11. The configuration of the scanning electron microscope according to the second embodiment may be substantially the same as that of the first embodiment (FIG. 1). The procedure of measuring an overlay shift amount can be also performed by the procedure which is substantially the same as that illustrated in the flowcharts of FIGS. 4 to 7. Here, according to the second embodiment, processes of an acquisition condition setting screen of Step S303c are different from those of the first embodiment.

According to the second embodiment, in the acquisition condition setting screen, a scanning method can be selected, and for example, bidirectional scanning can be selected as the scanning method. In other words, in the second embodiment, an added image can be generated by adding an image obtained by differentiating irradiation trajectories of the electron beams. Depending on a combination of a sample to be a measurement target and a scanning direction of electron beams, the overlay measurement accuracy may decrease. Specifically, an image formed by a detected electron signal may not correctly reflect unevenness of the sample.

For example, even in a case of a line pattern in which the left edge and the right edge are symmetrical, the shape of a secondary electron signal obtained by scanning the wafer with the electron beams in one direction from the left side to the right side may not symmetrical due to the edge effect and the like. The shape of the backscattered electron signal may not be symmetrical due to the detector characteristics and the like.

In the second embodiment, in step S303c, it is possible to set a scanning method for reducing the influence of the edge effect, the detector characteristics, and the like. Thereby, errors based on the target sample and the shape of the detected electronic signal can be reduced.

FIG. 11 is an example of the acquisition condition setting screen of the present embodiment. The difference from the first embodiment (FIG. 9) is that the image generating condition setting area 603 includes a scanning method setting area 801. In the area, it is possible to set a direction of scanning electron beams. Accordingly, it is possible to acquire an image by reducing the difference in the shape of the electronic signal to be detected according to the characteristics of the target sample, and thus the overlay measurement can be performed with high accuracy.

For example, when the edge effect becomes a main cause of the error, a method (bidirectional scanning) of scanning the electron beams from the left side to the right side and then scanning the same position from the right side to the left side is considered. According to the scanning method, it is possible to obtain a secondary electron signal in which the edge effects of the left edge and the right edge is made uniform by calculating an average of a first electron signal obtained by scanning from the left side to the right side and a second electron signal obtained by scanning from the right side to the left side.

When the detector characteristics are the main cause of the error, a method of performing scanning while the scanning direction is rotated for each specific angle can be considered. According to the scanning method, images obtained from scanning directions of a plurality of different angles are rotated using pattern matching or the like so that the target samples are in the same direction, and the average of the images is calculated, so that the influence of the detector characteristics depending on a specific angle can be reduced.

The scanning method and the method of generating an image are not limited to the above content. It is sufficient if the difference of the shape of the electron signals detected from the target sample can be reduced by appropriately selecting the combination of the target sample and the scanning directions of the electron beams.

As described above, according to the second embodiment, the same effects as those of the first embodiment can be obtained. In the second embodiment, since the scanning method of the electron beams can be selected, it is possible to reduce the difference between the shapes of the electron signals according to the characteristics of the target sample and perform the overlay shift measurement with high accuracy.

### Third Embodiment

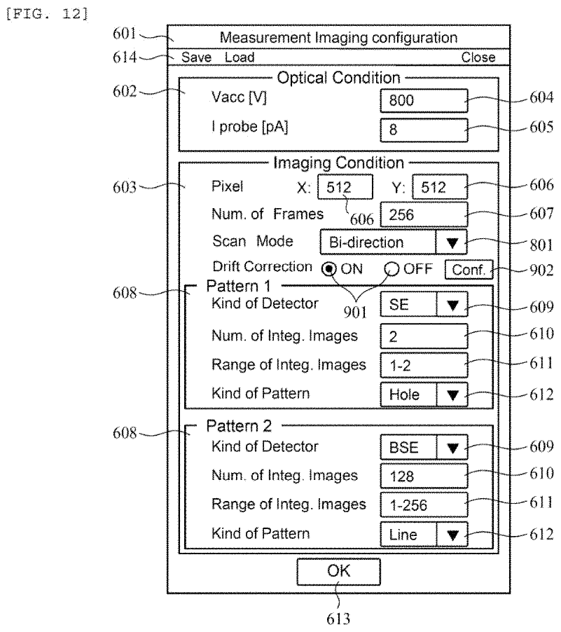

Subsequently, a scanning electron microscope (SEM) as a charged particle beam system according to a third embodiment is described with reference to FIG. 12. The configuration of the scanning electron microscope of the third embodiment may be substantially the same as that of the first embodiment (FIG. 1). The procedure of measuring an overlay shift amount can be performed through a procedure substantially the same as that illustrated in the flowcharts of FIGS. 4 to 7. Here, according to the third embodiment, in addition to a scanning method setting area 801, whether drift correction is to be performed (is required) can be selected.

In a scanning electron microscope, drift may occur due to charging of the target sample and affect the accuracy of the overlay shift measurement. For example, when a plurality of images are captured and added to generate an added image, if the target sample is charged by electron beam irradiation, the charge amount differs between the plurality of images captured at different timings. In this case, the effect of the drift differs among the plurality of images to be added, and there is concern in that even if the images are added, an added image with a sufficient resolution cannot be obtained.

For this reason, in the scanning electron microscope according to the third embodiment, whether drift correction is performed can be selected on the setting screen so as to reduce the influence of drift at the time of image addition in Step S303c. Therefore, when the drift correction is performed, a plurality of images after the drift correction is performed are added to be an added image. When it is determined that the drift correction is required, by selecting the setting for performing the drift correction, the blurriness of the added image due to the drift can be reduced.

FIG. 12 is an example of the acquisition condition setting screen according to the third embodiment. The difference from the screen (FIG. 11) of the second embodiment is to include a drift correction application necessity setting area 901 and a drift correction condition setting button 902, in addition to the scanning method setting area 801. In the drift correction application necessity setting area 901, whether drift correction is required to be applied (ON/OFF) is set in order to reduce the blurriness of the added image due to the drift occurring from the combination of the target sample and optical conditions.

By applying the correction, in S303d or S403, an added image or a template image with reduced blurriness in the drift direction can be acquired, and a decrease in overlay measurement accuracy can be prevented. A specific correction method for reducing the blurriness of the added image due to the drift is described in JP-A-2013-165003. According to the correction method, a target sample with high charged particle beam sensitivity and a target sample with a periodic pattern can be appropriately corrected.

Here, in the above correction method, since the position shift amounts between the single frame images are corrected, it is considered that, the lower layer 204 with a low SN ratio of a single frame image may not be appropriately corrected. Therefore, in the present embodiment, detailed drift correction conditions can be set with a drift correction condition setting screen 1001 displayed by clicking the drift correction condition setting button 902.

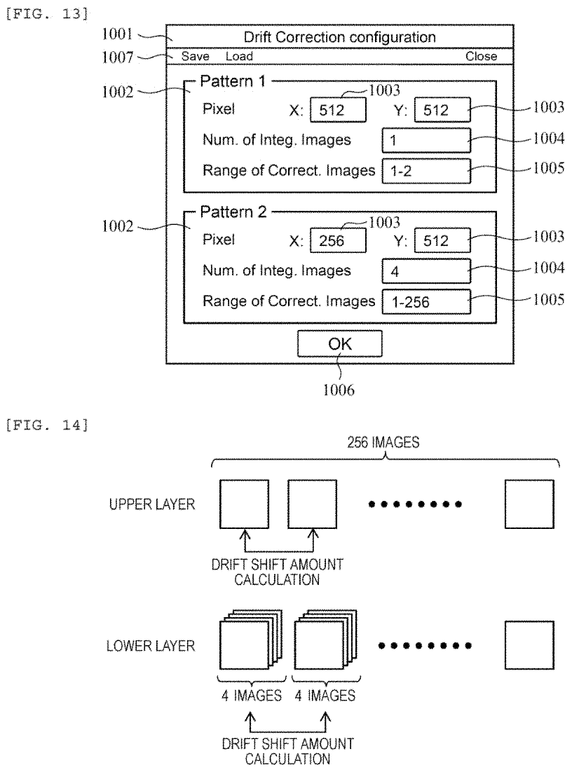

FIG. 13 is an example of the drift correction condition setting screen, and drift correction condition setting areas 1002 are arranged in the drift correction condition setting screen 1001. According to the present embodiment, since drift correction conditions are independently set with respect to each of the patterns of the upper layer and the lower layer, two drift correction condition setting areas 1002 are arranged, but this is merely an example, and the present invention is not limited to the present form.

For example, the drift correction condition setting areas 1002 include a drift amount detection region setting area 1003, a drift correction target image added number setting area 1004, and a drift correction target image range setting area 1005.

The drift amount detection region setting area 1003 is an area for setting a range used for detecting a drift amount with respect to the captured image. The drift correction target image added number setting area 1004 is an area for setting an added number of images with respect to the image which is the drift correction target. The drift correction target image range setting area 1005 is an area for setting a range of the image to be the drift correction target.

After the condition of the drift correction is confirmed by setting an added number of images and the range of the image used in the calculation of the drift amount in the drift correction condition setting areas 1002, if the condition confirmation button 1006 is clicked, the drift correction condition is stored in the control unit 20. With a setting screen operating unit 1007, the set drift correction condition can be stored and read, and the once set drift correction condition can be reused.

With reference to FIG. 14, a method of detecting a drift shift amount according to the third embodiment is described. In the present embodiment, in view of the drift shift amounts different between the upper layer and the lower layer, a method of detecting drift shift amounts different between the upper layer and the lower layer is employed.

For example, in the upper layer, among the plurality (for example: 256 images) of first images P1, the first and second images with a less shape change due to the image electron beam irradiation are used as targets, and a drift shift amount is detected by using 512×512 pixels of the detected image.

Meanwhile, in the lower layer, the plurality of second images P2 are added for each adjacent small unit (for example, 4 images), the plurality of intermediate images are generated, and the drift shift amounts between the intermediate images are detected. In order to prevent erroneous detection due to a plurality of line patterns, drift shift amounts are detected by using 256×512 pixels of the detected image. In the lower layer, since the SN ratio around one image is low, erroneous detection can be prevented by generating an intermediate image in this way.

According to the present embodiment, the drift shift amounts can be calculated from the image with a small shape change due to the electron beam irradiation in the upper layer, the intermediate image is generated from the individual images in the lower layer to increase the SN ratio, and then the drift shift amount can be detected. Accordingly, appropriately drift correction can be performed on both of the upper layer and the lower layer. Since the drift shift amount can be detected in a state where the blurriness to the drift direction is reduced, as a result, the accuracy of overlay shift amount measurement can be increased.

The present invention is not limited to the above embodiments but includes various modifications. For example, the above embodiments are described in detail for easier understanding of the present invention, and the present invention is not limited to necessarily include all the configurations described above. For example, a device including a calculation unit that is connected to the charged particle beam system via the network separately from the control unit that controls the charged particle beam system can be included in the range of the present invention. With such a configuration, the charged particle beam system only acquires an image and the calculation unit performs other processes such as template position search or overlay shift amount calculation so that the efficient measurement becomes possible without being limited by the speed of a process other than the physical mechanism such as the stage.

Other configurations can be added to the configurations of the embodiments as appropriate, or components can be deleted or replaced. The configurations, functions, processing units, processing means, and the like described in the embodiments may be realized in hardware by designing a part or all of them using, for example, an integrated circuit. The above configurations, functions, processing units, processing means, and the like may be realized with software by interpretation and execution of a program for realizing each function by a processor. Information such as a program, a table, and a file for realizing each function can be stored on a recording device such as a memory, a hard disk, and a solid state drive (SSD), or a recording medium such as an IC card, an SD card, or DVD. The control lines and the information lines are illustrated to be necessary for the explanation, and not all the control lines and the information lines on the product are necessarily illustrated. In fact, almost all components may be considered to be interconnected.

1. A charged particle beam system comprising:
a charged particle beam irradiating unit that irradiates a sample with charged particle beams;
a detector that detects a signal from the sample; and
a computer system that measures an overlay shift amount between a first layer of the sample and a second layer lower than the first layer based on output of the detector, wherein
the computer system is configured to
generate first images with respect to the first layer and second images with respect to the second layer based on the output of the detector,
generate a first added image by adding the first images by a first added number of images and generate a second added image by adding the second images by a second added number of images greater than the first added number of images, and
measure an overlay shift amount between the first layer and the second layer based on the first added image and the second added image.

2. The charged particle beam system according to claim 1,
wherein the computer system is configured to perform a matching process between a first template image and the first added image, perform a matching process between a second template image and the second added image, and measure an overlay shift amount between the first layer and the second layer according to results of the matching processes.

3. The charged particle beam system according to claim 1,
wherein the computer system generates the first images based on information of secondary electrons generated by irradiating the sample with the charged particle beams and generates the second images based on information of backscattered electrons generated by irradiating the sample with the charged particle beams.

4. The charged particle beam system according to claim 1,
wherein the computer system is configured to set the first added number of images and the second added number of images.

5. The charged particle beam system according to claim 4,
wherein the computer system is configured to be able to set what number of image to be selected, among a plurality of captured images in addition to the first added number of images and the second added number of images.

6. The charged particle beam system according to claim 1,
wherein the computer system generates the first added image and the second added image by adding a plurality of images obtained by differentiating irradiation trajectories of the charged particle beams.

7. The charged particle beam system according to claim 1,
wherein the computer system generates the first added image and the second added image by adding images after drift correction for reducing an influence due to drift.

8. The charged particle beam system according to claim 7,
wherein the computer system generates a plurality of intermediate images by adding the second images for each third number of images smaller than the second added number of images when the second images are added by the second added number of images, and performs the drift correction according to a shift amount between the plurality of intermediate images.

9. An overlay shift amount measurement method of measuring an overlay shift amount between different layers of a sample based on a signal detected by a detector by irradiating the sample with charged particle beams, the method comprising:
a step of generating first images with respect to a first layer of the sample and second images with respect to a second layer lower than the first layer based on output of the detector;
a step of generating a first added image by adding the first images by a first added number of images and generating a second added image by adding the second images by a second added number of images greater than the first added number of images; and
a step of measuring an overlay shift amount between the first layer and the second layer based on the first added image and the second added image.

10. The overlay shift amount measurement method according to claim 9, further comprising:
a step of performing a matching process between a first template image and the first added image and performing a matching process between a second template image and the second added image,
wherein the overlay shift amount measurement is performed according to results of the matching processes.

11. The overlay shift amount measurement method according to claim 9,
wherein the first images are generated based on information of secondary electrons generated by irradiating the sample with the charged particle beams, and the second images are generated based on information of backscattered electrons generated by irradiating the sample with the charged particle beams.

12. The overlay shift amount measurement method according to claim 9, further comprising:
a step of setting the first added number of images and the second added number of images.

13. The overlay shift amount measurement method according to claim 12,
wherein the step of setting the first added number of images and the second added number of images includes setting what number of image to be selected, among a plurality of captured images.

14. The overlay shift amount measurement method according to claim 9,
wherein the first added image and the second added image are generated by adding a plurality of images obtained by differentiating irradiation trajectories of the charged particle beams.

15. The overlay shift amount measurement method according to claim 9,
wherein, in generation of the first added image and the second added image, the first added image and the second added image are generated by adding an image after drift correction for reducing an influence due to drift.

16. The overlay shift amount measurement method according to claim 15,
wherein, when the second images are added by the second added number of images, a plurality of intermediate images are generated by adding the second images for each third number of images smaller than the second added number of images, and the drift correction is performed according to a shift amount between the plurality of intermediate images.
